(19) United States
(12) Patent Application Publication
(10) Pub. No.: US 2009/0090956 A1
(43) Pub. Date: Apr. 9, 2009

(54) Flash Memory Device and Method of Manufacturing Flash Memory Device

(76) Inventor: Yong Ho OH, Bupyeong-gu (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/244,742

(22) Filed: Oct. 2, 2008

(30) Foreign Application Priority Data
Oct. 4, 2007 (KR) 10-2007-0099611

(51) Int. Cl. H01L 21/28; H01L 29/788

(52) U.S. Cl. 257/316; 438/593; 257/E21.209; 257/E29.3

(57) ABSTRACT

Provided is a flash memory device and a method of manufacturing the same. In the method, a tunnel oxide layer pattern and a first polysilicon pattern are formed on a semiconductor substrate. A first dielectric layer including a first oxide layer, a first nitride layer, a second oxide layer, a second nitride layer and a third oxide layer is formed on the semiconductor substrate including the first polysilicon pattern. A second polysilicon pattern is formed on the dielectric layer pattern. The flash memory device includes a tunnel oxide layer pattern and a first polysilicon pattern on a semiconductor substrate; a dielectric layer on the first polysilicon pattern, including a first oxide layer pattern, a first nitride layer pattern, a second oxide layer pattern, a second nitride layer pattern and a third oxide layer pattern; and a second polysilicon pattern on the dielectric layer pattern.

### CROSS-REFERENCE TO RELATED APPLICATIONS

The present application claims the benefit under 35 U.S.C. §119 of Korean Patent Application No. 10-2007-0099611, filed Oct. 4, 2007, which is hereby incorporated by reference in its entirety.

### BACKGROUND

Embodiments of the invention relate to a flash memory device and a method of manufacturing the same.

A flash memory device is a type of non-volatile memory, which maintains stored data even when its power is turned off. It has an advantage in that data processing speed in write, read and delete (erase) operations is comparatively high. Accordingly, the flash memory device is widely used as a data storage device for the BIOS of personal computers (PC), set-top boxes, printers and network servers, and is frequently employed in cameras, cellular phones, etc., in recent years.

However, as the flash memory device is miniaturized and the thickness of certain dielectric layers (e.g., an ONO layer) decreases, a data retention problem may arise due to stress generated in forming the ONO layer. As a result, the device characteristics may suffer and/or deteriorate.

### SUMMARY

In one embodiment, a method of manufacturing a flash memory device comprises: forming a tunnel oxide layer pattern and a first polysilicon pattern on a semiconductor substrate; forming a first dielectric layer including a first oxide layer, a first nitride layer, a second oxide layer, a second nitride layer and a third oxide layer on the semiconductor substrate including the first polysilicon pattern; patterning the first dielectric layer to form a dielectric layer pattern; and forming a second polysilicon pattern on the dielectric layer pattern.

In another embodiment, a flash memory device comprises: a tunnel oxide layer pattern and a first polysilicon pattern on a semiconductor substrate; a dielectric layer on the first polysilicon pattern, the dielectric layer including a first oxide layer pattern, a first nitride layer pattern, a second oxide layer pattern, a second nitride layer pattern and a third oxide layer pattern; and a second polysilicon pattern on the dielectric layer pattern.

The details of one or more embodiments are set forth in the accompanying drawings and the description below. Other features will be apparent from the description and drawings, and from the claims.

### BRIEF DESCRIPTION OF THE DRAWINGS

FIGS. 1 to 8 are sectional views illustrating a method of manufacturing a flash memory device according to various embodiments.

### DETAILED DESCRIPTION OF THE EMBODIMENTS

A flash memory device and a method for manufacturing the same according to embodiments of the invention will be described in detail with reference to the accompanying drawings. In the description of such embodiments, it will be understood that when a layer (or film) is referred to as being ‘on’ another layer or substrate, it can be directly on another layer or substrate, or one or more intervening layers may also be present.

In the drawings, the thickness or size of each layer is exaggerated, omitted, or schematically illustrated for convenience in description and clarity. Also, the size of each element does not entirely reflect the actual size.

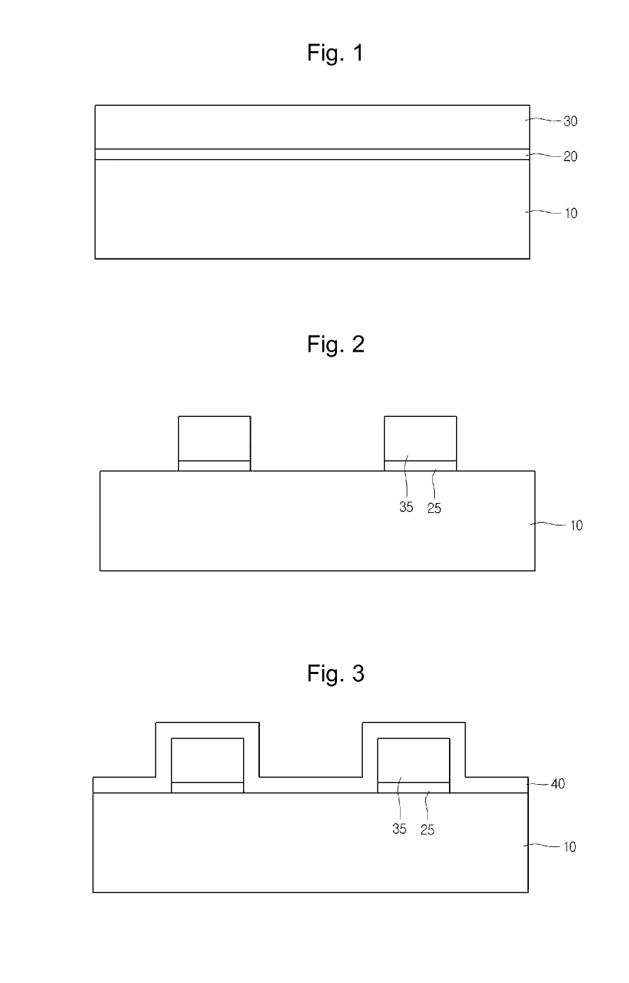

FIGS. 1 to 8 are sectional views illustrating an exemplary method of manufacturing a flash memory device according to embodiments of the invention.

As shown in FIG. 1, a tunnel oxide layer 20 and a first polysilicon layer 30 are formed on a semiconductor substrate 10. The tunnel oxide layer may be formed by wet or dry thermal oxidation of the semiconductor (e.g., single crystal silicon) substrate 10, and the first polysilicon layer 30 may be formed by chemical vapor deposition (CVD, which may be plasma-assisted) of silicon from a silicon source such as a silane gas (e.g., SiH₄, Si₂H₆) and crystallization (e.g., by annealing [e.g., rapid thermal annealing, or RTA]).

Next, as shown in FIG. 2, the tunnel oxide layer 20 and the first polysilicon layer 30 are patterned to form a tunnel oxide layer pattern 25 and a first polysilicon pattern 35. The first polysilicon pattern 35 may function as a floating gate. Alternatively, the patterning step can be performed later, after deposition of the ONONO dielectric layer and the second polysilicon layer.

Next, as shown in FIG. 3, a first nitride layer 40 is formed on the semiconductor substrate 10, including on and/or over the tunnel oxide layer pattern 25 and on the first polysilicon pattern 35. At this time, the first nitride layer 40 may have a thickness in the range of 20˜50 Å (e.g., 30˜40 Å).

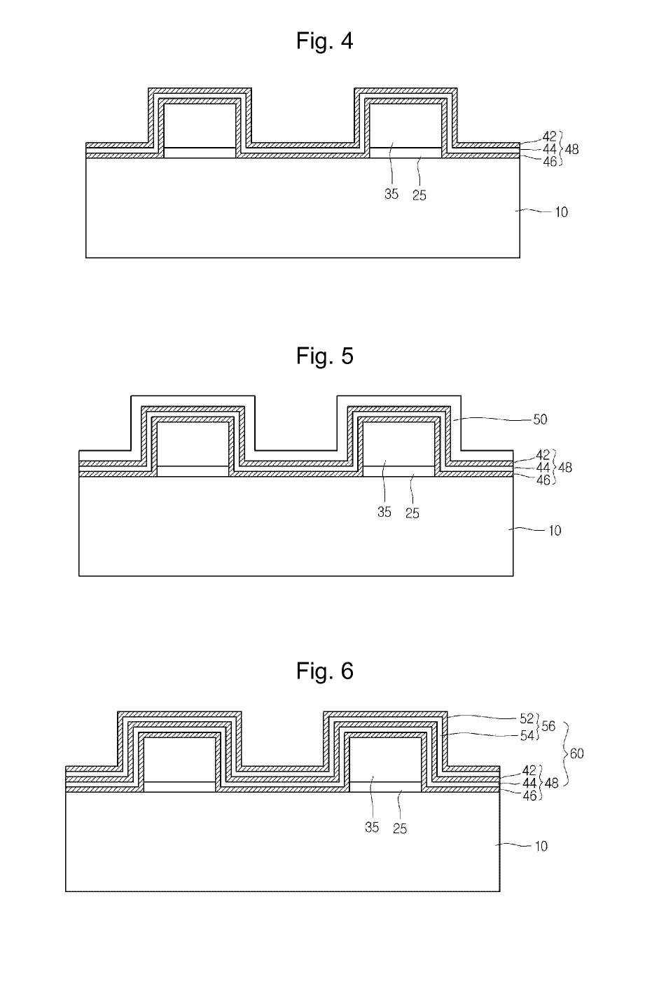

Next, as shown in FIG. 4, a first thermal process is performed with respect to the semiconductor substrate 10 and/or the first nitride layer 40 to form a first dielectric layer 48. The first thermal process comprises a RTP (Rapid Thermal Process), and is performed in an oxidizing atmosphere (e.g., containing or consisting essentially of O₂, O₃, N₂O, NO and/or NO₂ gas, alone or combined with an inert/noble gas such as Ar). An upper portion (e.g., at the uppermost and/or outermost surface) and a lower portion of the first nitride layer 40 and/or an outermost portion of the first polysilicon layer 30 (e.g., at the lowermost and/or innermost surface of the first nitride layer 40) are oxidized by the first thermal process.

The first thermal process is performed such that oxygen can be diffused to a contact portion between the first nitride layer 40 and the first polysilicon pattern 35. That is, a first dielectric layer 50 including a first oxide layer 46 (at an interface between the first nitride layer 40 and first polysilicon layer 30), a nitride layer 44 and a second oxide layer 42 (from the uppermost and/or outermost portion of the first nitride layer 40) is formed by the first thermal process. Thus, the first nitride layer 40 may be considered to be a first “nitride pre-dielectric” layer.

Next, as shown in FIG. 5, a third nitride layer 50 is formed on the first dielectric layer 48. The third nitride layer 50 may have a thickness in the range of 60˜80 Å, and be formed using plasma deposition process (e.g., plasma-enhanced CVD [PE-CVD], etc.).

Next, as shown in FIG. 6, a second thermal process is performed with respect to the semiconductor substrate 10 and/or the third nitride layer 50 to form a second dielectric layer 56 on the first dielectric layer 48. The second thermal process also comprises an RTP, and is performed in an oxidizing atmosphere, as described herein (e.g., comprising or consisting essentially of 02 gas). An uppermost or outermost portion of the third nitride layer 50 is oxidized by the second thermal process.

The second thermal process is performed such that only the uppermost or outermost portion of the third nitride layer 50 is oxidized. By the second thermal process, the second dielectric layer 56 including a fourth nitride layer 54 and a third oxide layer 52 is formed. Thus, the third nitride layer 50 may be considered to be a second “nitride pre-dielectric” layer.

By forming the second dielectric layer 56, a dielectric layer 60 including the first oxide layer 46, the second nitride layer 44, the second oxide layer 42, the fourth nitride layer 54 and the third oxide layer 52 is formed on the semiconductor substrate 10, on and/or over the tunnel oxide layer pattern 25 and on the first polysilicon pattern 35, including sidewalls thereof. Alternatively, both nitride layers 40 and 50 may be sequentially deposited and oxidized on the unpatterned tunnel dielectric and first polysilicon layers.

The third dielectric layer 60 functions to insulate an upper layer thereon (e.g., a control gate) from a lower layer therebeneath (e.g., a floating gate), and the first polysilicon pattern 35 is surrounded all on sides (other than the interface with the tunnel dielectric 20) by the third dielectric layer 60.

The third dielectric layer 60 formed as above may have a dielectric constant higher than a related art ONO dielectric layer. Also, the third dielectric layer 60 may have a thickness in the range of 10-20 nm (e.g., 13-15 nm).

Thus, embodiments of the invention can effectively decrease the EOT (Equivalent Oxide Thickness) of an interpoly dielectric and can enhance the coupling ratio of flash memory cells. Also, since the thermal process is performed with respect to the nitride contacting the first polysilicon pattern 35 functioning as the floating gate to minimize the generation of stress, data retention characteristics can be improved.

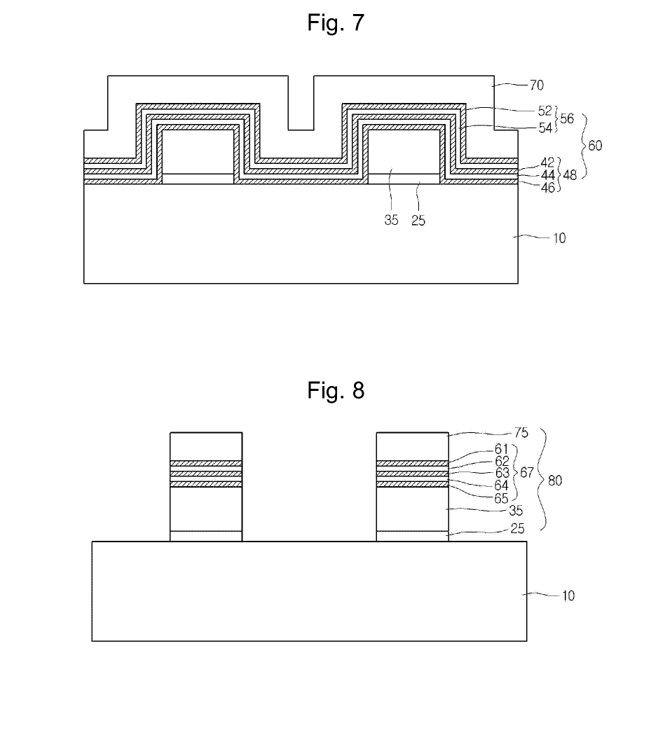

Next, as shown in FIG. 7, a second polysilicon layer 70 is formed on the third dielectric layer 60, generally in the same or a similar manner is the first polysilicon layer 30.

Next, as shown in FIG. 8, the third dielectric layer 60 and the second polysilicon layer 70 are patterned (e.g., by photolithographic masking and etching to form a dielectric layer pattern 67 and a second polysilicon pattern 75. That is, a gate 80 including the tunnel oxide layer pattern 25, the first polysilicon pattern 35, the dielectric layer pattern 67 and the second polysilicon pattern 75 may be formed. Lightly doped source/drain extensions (e.g., LDD's; not shown) can then be formed in the substrate 10 by ion implantation.

The dielectric layer pattern 67 includes a first oxide layer pattern 65, a second nitride layer pattern 64, a second oxide layer pattern 63, a fourth nitride layer pattern 62, and a third oxide layer pattern 61 (i.e., an ONONO pattern).

The second polysilicon pattern 75 is a control gate, which may induce an electric field in and/or excite electrons existing in the underlying first polysilicon pattern 35 and provide a bias voltage for charging or discharging to be applied.

In the case where the second polysilicon layer 70 is deposited over an unpatterned dielectric layer 60 and first polysilicon layer 30, the entire stack (second polysilicon layer 70, unpatterned ONONO dielectric layer 60 and first polysilicon layer 30) can be patterned in a single photolithographic patterning and etching sequence to for the structure of FIG. 8.

Next, although not shown in the drawings, a spacer may be formed on a sidewall of the gate 80 and a source and drain region may be formed in the semiconductor substrate 10.

In one embodiment following the general process of FIGS. 1-8, the first polysilicon pattern 35 can have a width greater than the second polysilicon pattern 75. This allows for formation of lightly doped source/drain extensions in the substrate 10 by ion implantation following formation of the first polysilicon pattern 35 (e.g., between FIGS. 2 and 3), formation of first sidewall spacers (e.g., by anisotropic etching of one or more of the individual ONONO layers; not shown) following formation of the second polysilicon pattern 75 by selective etching of polysilicon relative to oxide layer 52, and formation of source/drain terminals in the substrate 10 by ion implantation using the sidewall spacers as a mask.

In another embodiment following the general process of FIGS. 1-8, the first polysilicon pattern 35 can have a width smaller than the second polysilicon pattern 75. In this embodiment, lightly doped source/drain extensions are formed in the substrate 10 by ion implantation following formation of the first polysilicon pattern 35 (e.g., between FIGS. 2 and 3, as described above), and formation of the second, wider polysilicon pattern 75 results in a kind of sidewall spacer (comprising 1, 3 or all 5 of the individual ONONO layers) along the sidewall of the first polysilicon pattern 35 by masking by the overlying second polysilicon pattern 75. As a result, in this embodiment, the second polysilicon pattern 75 generally has a width of at least the width of the first polysilicon pattern 35 and the thickness of the first oxide layer 46, but not greater than the width of the first polysilicon pattern 35 and the entire ONONO layer 60. Source/drain terminals may then be formed in the substrate 10 by ion implantation using the second polysilicon pattern 75 and the sidewall spacers as a mask.

FIG. 8 is a cross-sectional view of an exemplary flash memory device according to embodiments of the invention.

Referring to FIG. 8, the gate 80 is formed on the semiconductor substrate 10. The gate 80 includes the tunnel oxide layer pattern 25, the first polysilicon pattern 35, the dielectric layer pattern 67 and the second polysilicon pattern 75. The first polysilicon pattern 35 may function as a floating gate.

The dielectric layer pattern 67 includes the first oxide layer pattern 65, the second nitride layer pattern 64, the second oxide layer pattern 63, the fourth nitride layer pattern 62 and the third oxide layer pattern 61 (a so-called “ONONO” layer). The dielectric layer pattern 67 functions to insulate an upper layer thereon from a lower layer therebeneath. The dielectric layer pattern 65 may have a thickness in the range of 13˜15 nm.

The second polysilicon pattern 75 is a control gate, which may induce an electric field in and/or excite electrons existing in the underlying first polysilicon pattern 35 and provide a bias voltage to be applied for charging or discharging operations (e.g., programming and or erasing).

As described above, the flash memory device and the method of manufacturing the same according to embodiments can effectively decrease the EOT (Equivalent Oxide Thickness) of an interpoly dielectric to enhance the coupling ratio of the flash memory cells.

Also, since a thermal process is performed with respect to the nitride contacting the floating gate to minimize the generation of stress, the reliability of the flash memory device and the electrical characteristic can be enhanced.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a flash memory device comprising:
forming a tunnel oxide layer pattern and a first polysilicon pattern on a semiconductor substrate;
forming a first dielectric layer including a first oxide layer, a first nitride layer, a second oxide layer, a second nitride layer and a third oxide layer on the semiconductor substrate including the first polysilicon pattern;
patterning the first dielectric layer to form a dielectric layer pattern; and
forming a second polysilicon pattern on the dielectric layer pattern.

2. The method of claim 1, wherein forming the first dielectric layer comprises:
forming a second dielectric layer including the first oxide layer, the first nitride layer and the second oxide layer on the semiconductor substrate including the first polysilicon pattern; and
forming a third dielectric layer including the second nitride layer and the third oxide layer on the second dielectric layer.

3. The method of claim 2, wherein forming the second dielectric layer comprises:
forming a first nitride pre-dielectric layer on the semiconductor substrate including the first polysilicon pattern; and
performing a first thermal process to form the first dielectric layer including the first oxide layer, the first nitride layer and the second oxide layer.

4. The method of claim 3, wherein performing the first thermal process comprises forming the first oxide layer and the second oxide layer on and beneath the first nitride layer, respectively.

5. The method of claim 3, wherein performing the first thermal process comprises forming the first oxide layer and the second oxide layer at a lowermost surface of the first nitride pre-dielectric layer and from an uppermost surface of the first nitride pre-dielectric layer, respectively.

6. The method of claim 3, wherein performing the first thermal process comprises performing a first RTA (Rapid Thermal Anneal) in an atmosphere comprising O₂ gas.

7. The method of claim 3, wherein performing the first thermal process comprises diffusing oxygen to a contact portion between the first nitride pre-dielectric layer and the first polysilicon pattern.

8. The method of claim 2, wherein forming the third dielectric layer comprises:
forming a second nitride pre-dielectric layer on the second dielectric layer; and
performing a second thermal process to form the third dielectric layer including the second nitride layer and the third oxide layer.

9. The method of claim 8, wherein performing the second thermal process comprises forming the third oxide layer on the second nitride layer.

10. The method of claim 8, wherein performing the second thermal process comprises forming the third oxide layer from the second nitride pre-dielectric layer.

11. The method of claim 8, wherein performing the second thermal process comprises performing a second RTA in an atmosphere comprising O₂ gas.

12. The method of claim 1, wherein the second polysilicon pattern has a nominal width about equal to a nominal width of the first polysilicon pattern.

13. The method of claim 1, wherein the second polysilicon pattern has a width greater than a width of the first polysilicon pattern.

14. The method of claim 13, wherein the first dielectric layer including at least the first oxide layer is on sidewalls of the first polysilicon pattern.

15. A flash memory device comprising:
a tunnel oxide layer pattern and a first polysilicon pattern on a semiconductor substrate;
a dielectric layer on the first polysilicon pattern, the dielectric layer including a first oxide layer pattern, a first nitride layer pattern, a second oxide layer pattern, a second nitride layer pattern and a third oxide layer pattern; and
a second polysilicon pattern on the dielectric layer pattern.

16. The flash memory device of claim 15, wherein the dielectric layer pattern has a thickness in a range of 13˜15 nm.

17. The flash memory device of claim 15, wherein the second polysilicon pattern has a nominal width about equal to a nominal width of the first polysilicon pattern.

18. The flash memory device of claim 15, wherein the second polysilicon pattern has a width greater than a width of the first polysilicon pattern.

19. The flash memory device of claim 18, wherein the first dielectric layer including at least the first oxide layer is on sidewalls of the first polysilicon pattern.

20. The flash memory device of claim 19, wherein at least the first oxide layer, the first nitride layer pattern, and the second oxide layer pattern is on sidewalls of the first polysilicon pattern.
